(19) United States
(12) Patent Application Publication
(10) Pub. No.: US 2005/0225210 A1
(43) Pub. Date: Oct. 13, 2005

(54) Z-axis electrical connection and methods for ultrasound transducers

(75) Inventors: Stephen C. Englund, Bellevue, WA (US); Ellen M. Rowland, Bellevue, WA (US); Grazyna M. Palczewska, Bellevue, WA (US); Gregg W. Frey, Issaquah, WA (US); Todor Sheljaskow, Issaquah, WA (US); Lisa A. Fearn, Seattle, WA (US); Vaughn R. Marian, Saratoga, CA (US); Nelson H. Oliver, Sunnyvale, CA (US); Walter T. Wilser, Cupertino, CA (US); Worth B. Walters, Cupertino, CA (US)

Correspondence Address: Siemens Corporation;Intellectual Property Department, 170 Wood Avenue South, Iselin, NJ, 08830, US

(73) Assignee: Siemens Medical Solutions USA, Inc.

(21) Appl. No.: 10/815,307

(22) Filed: Apr. 1, 2004

(51) Int. Cl. H01L 41/18

(52) U.S. Cl. 310/334

(57) ABSTRACT

Electrical connection is provided in a transducer stack through a backing block. A flexible circuit is sandwiched between pieces of acoustic attenuating material. For example, 2 to 200 or more flexible circuits are stacked in alternating layers with pieces of acoustically attenuating material. The alternating layers are then connected together to form a backing block with Z-axis electrical connection. The top surface of the connected backing block includes a plurality of exposed electrical traces from the flex circuit. Since flex circuits are used, the electrical traces are precisely aligned along one dimension. Since pre-formed acoustic attenuating material pieces are used, precise alignment is provided along a second or orthogonal dimension. The substrate holding the electrical traces in the flexible circuits provides more stability and allows for easier connection to circuit boards as compared to individual strips of metal.

### BACKGROUND

The present invention relates to Z-axis electrical connection and methods for electrical connection in ultrasound transducers. In particular, backing blocks include electrical interconnections with transducer array elements as well as acoustic attenuating material.

For linear transducer arrays, a flex circuit with a number of traces equal to the number of elements in the array is connected with the array. Electrical signals are transmitted to and from the array through the conductive traces of the flexible circuit. The flexible circuit is positioned between the transducer array and the backing block of acoustically attenuating material. Typically, the portion of the flexible circuit in contact with the transducer array is flat or lays in a same plane or curviplanar space as the bottom surface of the transducer array. U.S. Pat. No. 5,617,865, the disclosure of which is incorporated herein by reference, discloses using a single flexible circuit wrapped over the top of a backing block to connect to each element. For a multi-dimensional array having a few number of elements, such as 1.5D, 1.25D and 1.75D transducers, the same flex circuit configuration may be used. The density of electrical conductors on the flexible circuit may be increased due to any increased number of elements. However, as more elements are included within the transducer array, the conductor trace pitch decreases. As a result, a sufficient number of electrical traces may not be possible on a single flexible circuit. For multi-dimensional arrays, the act of dicing or separating individual elements in two dimensions may result in cutting through electrical conductors on the flex circuit.

One alternative to increase the number of possible electrical connections with the transducer array is a Z-axis connection. The Z-axis corresponds to a range dimension or a dimension substantially orthogonal to the transducer array. The elements of a multi-dimensional array are spaced along the elevation and azimuthal dimensions, but may include some Z-axis offsets due to a curve in the array. The electrical connections are provided through the acoustic attenuating material or backing block for connecting with the elements. For example, a plurality of flexible circuits extends along a Z-axis to connect with different groups of elements. Acoustically attenuating material is then molded around the flexible circuits. However, mixing and curing the acoustically attenuating material is time consuming and messy, especially while accounting for flexible circuits. In another approach, conductive strips or individual electrical connections are laminated with layers of acoustic attenuating material. However, multiple thin electrical traces being laminated with blocks of acoustic attenuating material may be unwieldy and difficult to avoid damage to the electrical strips. Where hundreds or even thousands of elements are provided, the number of electrical strips increases the difficulty in connecting the conductors and in laminating the alternating layers together.

### BRIEF SUMMARY

By way of introduction, the preferred embodiments described below include methods and systems for providing electrical connection to a transducer stack or through a backing block. A flexible circuit is sandwiched between pieces of acoustic attenuating material. For example, 2 to 200 or more flexible circuits are stacked in alternating layers with pieces of acoustically attenuating material. The alternating layers are then connected together to form a backing block with Z-axis electrical connection. The top surface of the connected backing block includes a plurality of exposed electrical traces from the flex circuits. Since flex circuits are used, the electrical traces are precisely aligned along one dimension. Since pre-formed acoustic attenuating material pieces are used, precise alignment is provided along a second or orthogonal dimension. The substrate holding the electrical traces in the flexible circuits provides more stability and allows for easier connection to circuit boards as compared to individual strips of metal.

In a first aspect, a transducer stack for electrical connection is provided. A backing block includes alternating layers of acoustic attenuating material and electrical trace supporting material extending along a Z-axis. The backing block is positioned adjacent to a transducer array of elements.

In a second aspect, a method for manufacturing a backing block is provided. Multiple pieces of acoustic attenuating material are stacked with flexible circuit material. The stacked materials are connected together.

In a third aspect, a backing block for Z-axis electrical connection is provided. A plurality of flexible circuits each has a plurality of electrical traces. A plurality of layers of acoustic attenuating material alternate with the flexible circuits. The electrical traces are exposed on a first surface from between the layers of acoustic attenuating material. The flexible circuits extend from the acoustic attenuating material on a side opposite the first surface.

The present invention is defined by the following claims, and nothing in this section should be taken as limitation on those claims. Further aspects and advantages of the invention are discussed below in conjunction with the preferred embodiments. Any of the aspects discussed above or the further aspects discussed below may be used independently or in combination. Any of the disclosure herein may be later claimed.

### BRIEF DESCRIPTION OF THE DRAWINGS

The components and the figures are not necessarily to scale, emphasis instead being placed upon illustrating the principles of the invention. Moreover, in the figures, like reference numerals designate corresponding parts throughout the different views.

FIG. 1 is a graphical representation of one embodiment of alternating layers in a backing block;

FIG. 2 is a graphical representation of one embodiment of a portion of a transducer stack;

FIG. 3 is a graphical representation of a portion of a flexible circuit in one embodiment;

FIG. 4 is a graphical representation of a piece of acoustic attenuating material in one embodiment; and

FIG. 5 is a flow chart diagram of one embodiment of a method for manufacturing a backing block and transducer stack with Z-axis electrical connectivity.

### DETAILED DESCRIPTION OF THE DRAWINGS AND PRESENTLY PREFERRED EMBODIMENTS

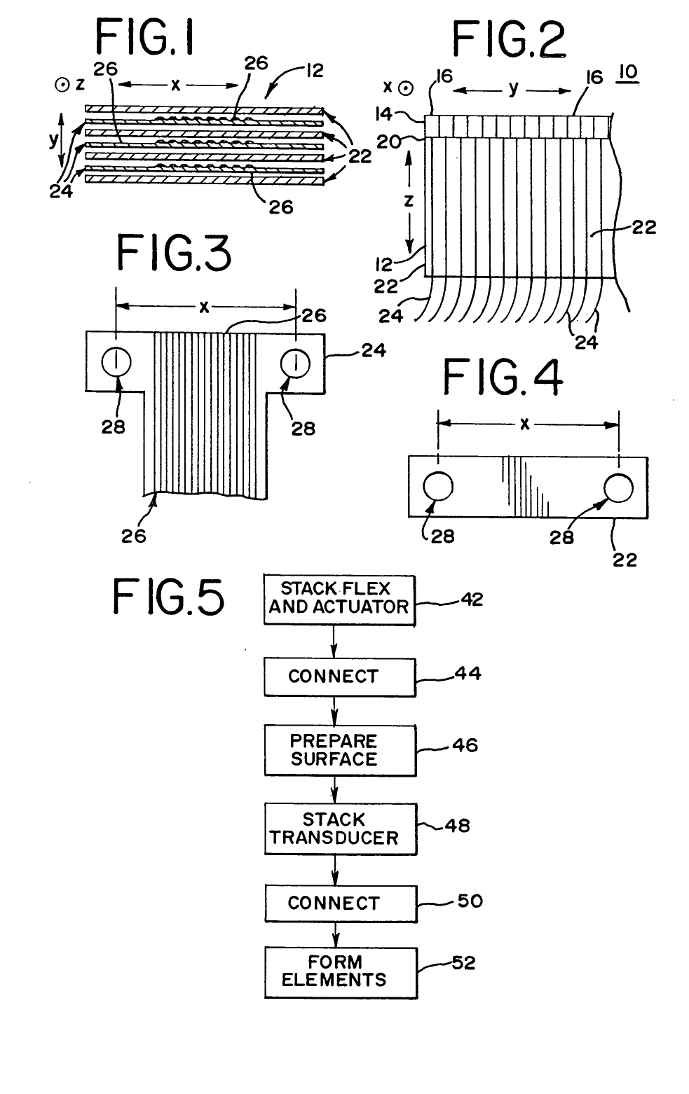

FIG. 1 shows a backing block for Z-axis electrical connection in one embodiment. FIG. 2 shows one embodiment of the backing block 12 used in a transducer stack 10 for electrical connection. The backing block 12 of FIG. 1 is a top view of a portion of the backing block 12, and the FIG. 2 view is a side view. X, Y and Z dimensions are shown in FIGS. 1 and 2. The Z dimension corresponds to a range dimension in ultrasound or phased array imaging. The X and Y dimensions correspond to elevation and azimuth dimensions, respectively or vice versa.

The transducer stack 10 shown in FIG. 2 includes a transducer array 14 of elements 16 and the backing block 12. Additional, different or fewer components may be provided, such as including matching layers or a lens layer in the transducer stack 10.

The elements 16 are transducer material, such as PZT, ceramic, silicon, semiconductor or membranes, but other materials or structures may be used to convert between acoustical and electrical energies. Each of the elements 16 is electrically and acoustically isolated from other elements 16. In one embodiment, a common ground plane is provided for all of the elements 16 with separate electrodes and associated inputs for each of the elements 16. The separate electrodes are provided on a bottom surface 20 of each of the elements 16, but may be on a top surface. The bottom surface 20 lies on a plane, but may be along a curved surface. The bottom surface 20 is positioned adjacent to the backing block 12. Acoustical energy is transmitted generally along the Z-axis by each of the elements 16. Undesired acoustical energy is attenuated by the backing block 12. The desired acoustical energy is transmitted away from the backing block into a patient.

The elements 16 of the transducer array 14 are distributed as a one-dimensional array or a multi-dimensional array. Multi-dimensional arrays are spaced along square, rectangular, hexagonal, triangular or other now known or later developed grid patterns. The elements 16 are fully sampled, but sparse sampling may be used. For square or rectangular grid patterns, the multi-dimensional array 14 includes M×N elements, such as where M extends along the X dimension and N extends along the Y dimension. The backing block 12 is positioned behind all or most of the elements 16 within the M×N extent of the array 14.

As shown in FIGS. 1 and 2, the backing block 12 includes alternating layers of acoustic attenuating material 22 and electrical trace supporting material 24. The acoustic attenuating material 22 acts to attenuate, absorb or reduce reflections of acoustic energy. The electrical trace supporting material 24 includes a plurality of electrical traces 26 for electrical connection with the elements 16. The electrical connections are isolated from each other. By orienting the electrical trace supporting material 24 and associated electrical conductors 26 along the Z-axis, the density of elements 16 and associated electrical connections is provided for implementing a multi-dimensional or two-dimensional transducer array.

The electrical trace supporting material 24 is a flexible circuit in one embodiment. For example, the electrical trace supporting material 24 is Kapton or other electrically nonconductive flexible material. A flexible circuit includes only traces or may include other active or passive circuit devices. In alternative embodiments, the electrical trace supporting material 24 is rigid or only semiflexible. Any now known or later developed support material may be used. For the flexible circuit embodiment, a single sided or double sided flexible circuit may be used. As shown in FIG. 1, the electrical trace supporting material 24 is a sheet of material with a plurality of electrical traces 26. Electrical traces 26 are conductors, such as copper, gold or other conductive material (e.g., polymer or metal). Within the backing block 12, a plurality of sheets or flexible circuits each having a plurality of electrical traces 26 are provided. The sheets of electrical trace supporting material 24 support the electrical traces 26 and may prevent contact of different electrical traces with each other within a sheet.

The electrical trace supporting material 24 is of any of various shapes. Blocks, plates, tubes or other structures of material may be used. In one embodiment shown in FIG. 3, a thin sheet of flexible circuit material is provided with tooling holes 28 spaced from the electrical traces 26. Electrical trace supporting material 24 without tooling holes 28 may be provided in other embodiments.

When the backing block 12 is assembled, the electrical traces 26 extend substantially orthogonal to a bottom surface of the transducer array 14. Substantially orthogonal is used herein to account an angular connection, the flexible circuits extending at an angle through the blocking block or some flexible circuits being at different angles to a curved array. FIG. 2 shows the flexible circuits or other electrical trace supporting material 24 extending orthogonal to the array 14. The sheets are positioned in parallel across the Y dimension. Each sheet is within a plane along the Z and X dimensions as shown in FIG. 2. By routing the traces vertical or along the Z dimension, the electrical connection is provided to each individual element 16 even after kerfing cuts to form the element 16 are performed. Use of a flexible circuit or other electrical trace supporting material 24 allows variations in the pitch and size of the traces 26 to correspond with the number and pitch of elements.

In one embodiment, the electrical traces 26 diverge from the z-axis within the backing block. For example, the electrical traces 26 diverge different amounts from orthogonal to the elements of the array 14. By diverging different amounts, the electrical traces spread apart by a greater amount than the pitch of the elements. The flexible circuits or electrical traces 26 have a first pitch adjacent to the elements, such as a same pitch as the elements. By diverging from orthogonal or along the z-axis, the pitch on a side of the backing block opposite the elements has a greater pitch, allowing for easier connection with bump bonding or flexible circuit connectors. Z-axis electrical connection is provided by traces 26 extending substantially along the z-axis in the backing block at the elements but also diverging from the z-axis. In one embodiment, the blocks of acoustic attenuating material are shaped, such as trapezoidal or with a curved surface, to provide the divergence. The electrical traces 26 may be exposed on a side, bottom or combinations thereof of the backing block due to the divergence.

For connection with the elements 16, each of the electrical traces 26 are plated at a portion adjacent to the respective element 16. For example, the traces 26 are plated for connection with an electrode of each element 16. In alternative embodiments, plating is not provided. In yet other alternative embodiments, electrodes for use with each of the elements 16 are formed at an exposed end of the electrical traces 26 for connection with the respective element 16.

The plurality of layers of acoustic attenuating material 22 alternate with the flexible circuits or electrical trace supporting material 24 within the backing block 12. The separate pieces of acoustic attenuating materials 22 are any now known or later developed materials for attenuating acoustic energy at 1 to 10 MHz. For example, the acoustic attenuating material 22 is cured epoxy loaded with fillers. Each layer of acoustic attenuating material 22 is a plate of material, such as a sheet of material for extending in a plane in parallel with the flexible circuits. FIG. 4 shows one embodiment of the slab, plate or piece of acoustic attenuating material 22. The height of the piece of acoustically attenuating material 22 is selected to provide desired acoustical attenuation. The thickness is selected to provide the desired pitch between traces 26 across layers. The width is selected to extend across the entire array 14 in one embodiment plus additional width for placement of the tooling holes 28. In alternative embodiments, any of the dimensions is different, such as providing multiple pieces of acoustically attenuating material 22 for sufficient width, thickness or height. Other alignment mechanisms than tooling holes 28 now known or later developed may be used. In alternative embodiments, the pieces of acoustically attenuating material 22 have different shapes, irregular shapes or vary in shapes between different pieces.

As shown in FIG. 1, each of the layers of electrical trace supporting material 24 are at least partially sandwiched between two layers of acoustically attenuating material 22 or other supporting material. At least partially sandwiched allows for the electrical trace supporting material 24 to extend beyond the acoustically attenuating material 22 as shown in FIG. 2 or elsewhere. FIG. 1 shows each of the layers 22, 24 with a space between them for ease of reference, but when connected together the layers are in contact or separated by bonding agent.

The pitch of the alternating layers 22, 24 is substantially the pitch between the elements 16 along at least one dimension. The pitch between the traces 26 is substantially the pitch between the elements 16 along a different dimension. By accounting for the thickness of the traces 26, the electrical trace supporting material 24 and the acoustic attenuating material 22, the distance between traces 26 across the alternating layers (e.g. along the Y dimension) is set to position the traces 26 along adjacent but different elements 16. The element size in azimuth is equal to the thickness of these materials plus any added thickness due to a bonding or laminating agent. The element size in elevation is substantially the same as the distance between the traces 26 along a flex circuit. Substantially is used to account for variations allowing the traces 26 to connect at different locations of elements 16 and to account for any sparse sampling of the array.

The alternating layers 22, 24 are bonded together in one embodiment. An epoxy or other binding agent is used to laminate the layers 22, 24 together. In alternative embodiments, a sintering, chemical or mechanical structure is used to hold the layers 22, 24 together. The electrical traces 26 are exposed at least on a first surface between the layers of acoustically attenuating material 22. The exposure on the surface allows for connection of the electrical traces 26 to the elements 16 of the transducer array 14. The flexible circuits or other electrical trace supporting material 24 extends from the back of the acoustically attenuating material 22 and the backing block 12 for electrical connection with cables or other circuits. In another embodiment, the flexible circuits or other electrical trace supporting material 24 terminates at the surface of the backing block for bump bonding or other subsequent electrical termination or connection.

The number of layers of electrical trace supporting material 24 is about equal to the number of elements extending along one dimension. The number of electrical traces 26 on each layer of electrical trace supporting material 24 is about the same number of elements 16 extending along a different dimension. For example in an M×N array, M layers of the electrical supporting material 24 is provided with N number of electrical traces 26 for each of the layers 24. An electrical trace 26 is provided for each of the elements 16 in the multi-dimensional array. In alternative embodiments, one or more of the sheets of electrical trace supporting material 24 is folded over to connect with more than one row or column of elements 16. One layer of the electrical trace supporting material 24 includes traces 26 for multiple rows of elements 16. As a result, fewer than M layers of the electrical trace supporting material 24 are provided.

In one embodiment, the number of layers of acoustically attenuating material 24 is equal to about the number of layers of electrical trace supporting material 24 plus one. The acoustic attenuating material 22 is alternated with layers of the electrical trace supporting material 24 so that a sandwich of acoustically attenuating material 22 is provided for each of the layers of electrical trace supporting material 24. In alternative embodiments, a fewer or greater number of layers of acoustically attenuating material 22 are provided. In one embodiment, the layers of acoustically attenuating material 22 at the extremities of the backing block 12 are thicker than other layers.

The term “about” used above for the number of layers provides for sparse sampling, the shorting together of elements, or other aperture processes that may allow for an inexact correspondence of the number of traces 26 along one dimension as compared to the number of elements 16.

In another embodiment, the electrical trace supporting material is the backing block pieces. For example, traces are deposited on the acoustic attenuating material pieces. Grooves are diced or molded into the pieces. Conductors are deposited on the pieces. The surface is then ground or etched so that the conductor in the grooves remains and conductors outside of the grooves are removed. Once stacked, the electrical traces 26 are provided on the surface adjacent the array for connection with the elements and on other surfaces for connection with system channels.

FIG. 5 shows one embodiment of a method for manufacturing a backing block and associated transducer stack. The method of FIG. 5 is used to construct the backing block shown in FIG. 1 using the materials shown in FIGS. 3 and 4 and to construct the transducer stack shown in FIG. 2. In other embodiments, one or more different materials, different backing blocks or different transducer stacks now known or later developed are used. Different, additional or fewer acts than shown in FIG. 5 may be provided. For example, acts 42 and 44 are provided without any of the following acts. As another example, the acts are performed in a different order.

In act 42, multiple pieces of acoustic attenuating material are stacked with flexible circuit materials. Any number of layers of material may be used. For example, at least two layers of flexible circuit material are stacked in an alternating fashion with pieces of acoustic attenuating material. In alternative embodiments, a single layer of flexible circuit material is stacked with two or more pieces of acoustic attenuating material. For use in a multi-dimensional array having M elements along one dimension, M layers of flexible circuit material are stacked alternating with M plus 1 layers of acoustic attenuating material. Greater numbers or lesser numbers of either or both of the flexible circuit material and the acoustic attenuating material may be used. Teflon tape or other protection may be used to prevent contact between different flex circuits or electrical traces.

The pieces of acoustic attenuating material and sheets of flexible circuit material are aligned for stacking to provide a desired distribution of electrical traces within the backing block. In one embodiment, the pieces of acoustic attenuating material and flexible circuit material are aligned with at least one tooling hole. For example, FIGS. 3 and 4 show flexible circuit material and acoustic attenuating material with tooling holes 28 on each side of the plate or sheet of material. A tooling form is used to maintain the relative position of the layers of material through alignment with the tooling holes 28. Additional or fewer tooling holes or other alignment/datum features may be used in other embodiments. Different alignment techniques may be used in other embodiments, such as stacking in a form without tooling holes. For one dimension, the traces are aligned by placement along the flexible circuit material. The traces are aligned for an orthogonal dimension by stacking the layers with a pitch substantially same as elements. Where elements have different sizes, different pitch may be provided within the backing block of the traces to correspond to the elements. Other variations due to sparse sampling or shorting of elements together may result in pitch variation of the traces along one or more dimensions within the backing block. Alternatively, the traces are maintained at the same or constant pitch but are either not used or are shorted together for operation with a same element.

In act 44, the stacked materials are connected together. For example, a bonding agent, such as an epoxy, is positioned between each of the layers of material for bonding the materials together. Pressure and/or heat are applied to connect the alternating layers together. The epoxy or other bonding agent acts to fill any gaps, such as associated with gaps caused by spaces between traces. In one embodiment, the bonding agent is selected as an acoustically attenuating material, such as an epoxy, for more efficient acoustic attenuation by the backing block. Other lamination or connection techniques now known or later developed for connecting multiple layers of the same or different materials together may be used. In one embodiment, the acoustic attenuating material is cleaned, such as using a plasma etch, an ultrasound treatment with a solvent or other now known or later developed cleaning or preparation for bonding. The flex circuit material may also be treated to increase the bond or connection.

In act 46, a surface of a backing block is prepared for stacking with the transducer. For example, a surface of the connected material is flattened. The surface for connection with the transducer array is flattened or otherwise shaped to conform to a bottom surface of the transducer array. The surface to be flattened has both acoustic attenuating material and flex circuit material exposed. The surface may have flex circuit or acoustic attenuating material extending higher than desired. By grinding, edging or other surface preparation, the surface is flattened, smoothed or otherwise prepared to expose the metal of the traces. Surface preparation may remove unwanted bonding agent.

Another preparation of the surface may include plating the exposed metal traces of the flexible circuit material. For example, the traces are shorted together and a current is applied in a bath to cause gold plating on the exposed ends of the traces. The gold plating may provide a better contact with the electrodes of the elements. The gold plating or other plating may also raise the exposed conductive material slightly above the surface of the backing block 12. As an alternative to plating the ends of the traces, the entire surface is plated or a metal conductor is otherwise deposited on the entire surface. The conductor is patterned, such as using conventional photolithographic techniques or is left without a pattern. For example, the metallization is used as the lower electrode for the transducer elements. Dicing kerfs to acoustically separate the transducer elements may extend deep enough to separate the layer of metallization into specific electrodes for each element. In yet other alternative embodiments, no plating or further metallization is provided.

In act 48, transducer material is stacked with the backing block of connected materials. The transducer material is a slab in one embodiment, but may be a composite material in other embodiments. For stacking, elements are previously defined or are not yet defined within the transducer material. The transducer material is positioned on a surface of the backing block where at least a portion of the flexible circuit material sandwiched between the acoustic attenuating material is substantially perpendicular to a bottom surface of the transducer material. The flexible circuit material and associated traces extend substantially along the Z-axis as shown in FIG. 2. The electrical traces extend through the backing block for connection with cable or other circuitry. The transducer material includes an electrode deposited on a bottom surface, but may be free of electrodes on the bottom surface. The transducer material is generally aligned with the backing block using tooling holes, a mold or general positioning. Where the transducer material includes an electrode on the bottom surface, the transducer material is stacked such that the exposed traces of the backing block make electrical contact with the transducer material.

In act 50, the connected materials of the backing block are bonded with the layer of transducer material. Using a same or different bonding agent, such as epoxy, the backing block is connected with the transducer material. Other now known or later developed lamination techniques for connecting the backing block to the transducer material may be used.

In act 52, elements are formed in the transducer material. For example, the layer of transducer material is diced into a multi-dimensional array of elements after the stacking or bonding of the transducer material with the backing block. In alternative embodiments, the dicing is performed along one dimension to define a linear array of elements. The dicing cuts extend through the transducer material and partially into the backing block. Since the electrical traces extend substantially orthogonal to the bottom surface of the transducer material, the dicing into the backing block material maintains the electrical path provided by the traces. As yet another alternative, the transducer material is diced or elements are otherwise formed prior to stacking on the backing block. For example, electrodes are etched, patterned or otherwise defined on a composite material to define the elements prior to stacking. As yet another example, a plate or slab of PZT material is diced and the resulting kerfs are filled with epoxy for maintaining relative positions. The diced transducer material is then stacked on the backing block.

While the invention has been described above by reference to various embodiments, it should be understood that many changes and modifications can be made without departing from the scope of the invention. For example, the axis for stacking the alternating layers of the backing block is at a non-orthogonal angle (e.g., 45 degree angle) to an axis along which elements are arranged. As another example, the traces extend through the backing block and into supporting material, such as more rigid or larger material for supporting the array stack. The stacked pieces include both the acoustically attenuating material and the supporting material. Alternatively, the flexible circuits or traces extend through the attenuating material, but not any supporting material.

It is therefore intended that the foregoing detailed description be regarded as illustrative rather than limiting, and that it be understood that it is the following claims, including all equivalents, that are intended to define the spirit and scope of this invention.

1. A method of manufacturing a backing block, the method comprising:
(a) stacking multiple pieces of acoustic attenuating material with flexible circuit material; and
(b) connecting the stacked materials together.

2. The method of claim 1 wherein (a) comprises aligning the pieces of acoustic attenuating material and flexible circuit material with at least one tooling hole.

3. The method of claim 1 wherein (a) comprises stacking M layers of flexible circuit material alternating with M+1 layers of acoustic attenuating material.

4. The method of claim 3 further comprising:
(c) positioning a layer of transducer material across the stack of (a), at least a portion of the flexible circuit material sandwiched between acoustic attenuating material being substantially perpendicular to a bottom surface of the transducer material; and
wherein (a) comprises stacking with a pitch of the layers of flexible circuit material a substantially same pitch as elements formed in the transducer material along a first dimension.

5. The method of claim 4 further comprising:
(d) forming the elements in the transducer material as a multi-dimensional array;
wherein traces in the flex circuits have a substantially same pitch as elements along a second dimension different than the first dimension.

6. The method of claim 1 wherein (b) comprises bonding the materials together.

7. The method of claim 1 further comprising:
(c) flattening a surface of the connected materials, the surface having both acoustic attenuating material and flexible circuit material exposed.

8. The method of claim 1 further comprising:
(c) plating exposed traces of the flexible circuit material.

9. The method of claim 1 further comprising:
(c) stacking the connected materials with a layer of transducer material, the layer of transducer material substantially orthogonal to traces of the flexible circuit material sandwiched between the acoustic attenuating material; and
(d) bonding the connected materials with the layer of transducer material.

10. The method of claim 9 further comprising:
(e) dicing the layer of transducer material into a multi-dimensional array of elements after (d);
wherein (a) comprises stacking at least two layers of flexible circuit material, traces from the at least two layers of flexible circuit material aligned with respective elements.

11. The method of claim 1 further comprising:
(c) terminating the flexible circuit material at a bottom surface of the connected materials.

12. The method of claim 1 further comprising:
(c) diverging a first flexible circuit from a second flexible circuit within the backing block.

13. A backing block for z-axis electrical connection, the block comprising:
a plurality of flexible circuits each having a plurality of electrical traces; and
a plurality of separate pieces of acoustic attenuating material alternating with the flexible circuits, the electrical traces exposed on a first surface from between the layers of acoustic attenuating material and the flexible circuits extending from the acoustic attenuating material on a side opposite the first surface.

14. The backing block of claim 13 wherein the electrical traces on the first surface have a first pitch along at least a first dimension and the flexible circuits have a second pitch greater than the first pitch along the first dimension on the side opposite the first surface.

15. A transducer stack for electrical connection, the stack comprising:
a transducer array of elements; and
a backing block comprising alternating layers of acoustic attenuating material and electrical trace supporting material, each layer of acoustic attenuating material being a separate block of acoustic attenuating material, the backing block adjacent to the elements and the electrical trace supporting material extending substantially along a z-axis from the elements and diverging from the z-axis within the backing block.

16. The transducer stack of claim 15 wherein the electrical trace supporting material comprises a flexible circuit.

17. The transducer stack of claim 15 wherein the transducer array comprises a multidimensional array of elements and wherein a pitch of the alternating layers at the elements is substantially the pitch between the elements along at least one dimension.

18. The transducer stack of claim 15 wherein the transducer array comprises a multidimensional array of M×N elements and wherein a first number layers of electrical trace supporting material is about M and a second number of electrical traces on each layer of the electrical trace supporting material is about N.

19. The transducer stack of claim 18 wherein about M+1 layers of the acoustic attenuating material alternate with the about M layers of electrical trace supporting material.

20. The transducer stack of claim 15 further comprising a plurality of electrical traces supported by the layers of electrical trace supporting material, the plurality of electrical traces extending substantially orthogonal to a bottom surface of transducer array, the elements spaced along the bottom surface.

21. The transducer stack of claim 15 further comprising:
an electrode on the bottom surface for each of the elements;
wherein each of the electrical traces is plated at a portion adjacent to a respective electrode.

22. The transducer stack of claim 15 wherein the alternating layers are bonded together.

23. The transducer stack of claim 15 wherein the layers of acoustic attenuating material comprise plates of material and the layers of electrical trace supporting material comprise sheets of material with traces, each of the layers of electrical trace supporting material at least partially sandwiched by two different layers of the acoustic attenuating material.

24. The transducer stack of claim 15 wherein at least two layers of electrical trace supporting material diverge by different amounts from orthogonal to the elements.

25. The transducer stack of claim 15 wherein the electrical trace supporting material comprises the layers of acoustic attenuating material, at least one of the layers of acoustic attenuating material having a plurality of grooves with electrical traces within the grooves.

26. The transducer stack of claim 15 wherein the electrical trace supporting material terminates at a surface of the backing block.
